(19) United States
(12) Patent Application Publication
(10) Pub. No.: US 2011/0272279 A1
(43) Pub. Date: Nov. 10, 2011

(54) APPARATUS FOR MANUFACTURING SEMICONDUCTOR DEVICE AND METHOD FOR MANUFACTURING SEMICONDUCTOR DEVICE BY USING THE SAME

(75) Inventors: Woo-Seok CHEONG, Daejeon (KR); Seong-Jae LEE, Daejeon (KR); Won-Ju Jo, Daejeon (KR); Moon-Gyu JANG, Daejeon (KR)

(73) Assignee: Electronics and Telecommunications Research Institute, Daejeon (KR)

(21) Appl. No.: 13/184,089

(22) Filed: Jul. 15, 2011

Related U.S. Application Data
(62) Division of application No. 10/527,056, filed on Oct. 20, 2005.

(30) Foreign Application Priority Data
Sep. 9, 2002 (KR) 10-2002-0054210

(51) Int. Cl. C23C 14/34

(52) U.S. Cl. 204/298.07

(57) ABSTRACT

In a process for manufacturing a hyperfine semiconductor device, an apparatus for manufacturing a semiconductor device such as a schottky barrier MOSFET and a method for manufacturing the semiconductor device using the same are provided. Two chambers are connected with each other. A cleaning process, a metal layer forming process, and subsequent processes can be performed in situ by using the two chambers, thereby the attachment of the unnecessary impurities and the formation of the oxide can be prevented and the optimization of the process can be accomplished.

### TECHNICAL FIELD

The present invention relates to an apparatus for manufacturing a semiconductor device and a method for manufacturing a semiconductor device by using the same, more particularly, to an apparatus for manufacturing a semiconductor device and a method for manufacturing a semiconductor device by using the same which optimize a new metal-junction type schottky barrier method in a process for manufacturing a hyperfine semiconductor device.

### BACKGROUND ART

The technique for manufacturing the hyperfine semiconductor device is an important technique that is a requisite for manufacturing the device having high integration and high speed. Recently, the methods for implementing the semiconductor device having a nano size are variously introduced and the method for manufacturing schottky barrier MOSFET using a metal silicide reaction need one of the highest level technique.

In the method for integrating the device equal to and larger than 100 nm by reducing the size thereof, the doping process for forming source and gate electrodes has many problems. If a schottky barrier is used in order to solve the problem due to the doping process, the resistance of the source/drain is remarkably lowered and a high-temperature heating process can be omitted. In doping process, heating process is necessary to form the source/drain electrode.

A schottky contact, contact between a metal layer and a silicon layer, generates an electronic energy barrier in the interface therebetween. It is known as Schottky Barrier Height (SBH), and its application to an infrared-ray sensor has been researched. Since the technique using schottky contact is brought out as an alternative of the nano electronic device in recent years, the optimized equipment and process therefor are not established yet. Accordingly, the SBH must be efficiently adjusted and the optimization of the hyperfine semiconductor device manufacturing process must be performed.

The technique using schottky contact has four types of problems in prior art.

First of all, there is a problem in a cleaning process performed before the metal depositing process. Generally, because the cleaning process can not be performed in situ, it can not prevent an extraneous substance for being generated between the metal and the silicon layer.

Secondly, it is difficult that the schottky contact is optimized in the fine structural aspect or the electronic characteristic aspect, due to the effect of a damage layer existed in the pattern, though the cleaning process was progressed to a certain extent.

Thirdly, since the loss of the silicon substrate is very large due to the over-etching in forming the gate electrode, it is difficult that the silicide is formed.

Fourthly, in case where the heating process is progressed in ex-situ after the metal layer is formed, it is difficult that the metal grain boundary oxidation is avoided.

Hereinafter, the structure of a schottky barrier (SB) MOSFET will be described with reference to FIG. 1.

A silicon layer 12 is formed on an insulating film 10 of a SOI (Silicon On Insulator) substrate. A gate oxide film 14 is formed on the silicon layer 12, and a gate electrode 16 is formed on the gate oxide film 14. And then, a spacer 16 is formed and is etched. In most of the hyperfine integrated-device, after the process for forming the spacer 16 is finished, a process for forming metal silicide is performed. However, when the spacer 16 is formed, the silicon layer 14 is frequently over-etched by a large amount. Thereafter, the wet-type cleaning process or the dry-type cleaning process is performed and then the metal deposition and heating processes are performed.

However, at this time, the following problems may be generated.

(1) The generation of the native oxide film cannot be prevented, before the metal depositing process.

(2) The silicide reaction is influenced by the damage generated in the etching process.

(3) Since the silicon layer is etched in great quantity, the optimization of the silicide process can not be easily accomplished.

(4) In the heating process for forming the silicide, additional oxidation can not prevented.

### DISCLOSURE OF INVENTION

In order solve the above-mentioned problems, an aspect of the present invention relates to an apparatus for manufacturing a semiconductor device which comprises a first chamber having a first substrate holder provided in the lower portion of the first chamber for mounting a sample thereon, a halogen lamp provided in the upper portion of the first chamber for irradiating lamp light to the sample, and a substrate door through which the sample passes; a second chamber having a temperature-adjustable second substrate holder provided in the lower portion of the second chamber for mounting the sample thereon, a middle film provided in the middle portion of the second chamber for dividing the chamber into an upper portion and a lower portion, an elevating portion attached to the second substrate holder for moving the second substrate holder into the upper portion or the lower portion on the basis of the middle film, and a metal depositing portion provided in the upper portion of the second chamber; pumping portions connected to the first chamber and the second chamber, for adjusting the pressures thereof; respectively; gas injecting portions connected to the first chamber and the second chamber, for injecting a gas by a certain amount, respectively; and a connecting portion for allowing the sample to reciprocally moving between the first chamber and the second chamber, without injecting outside air, wherein the connecting portion includes a gate valve.

Preferably, the metal depositing portion includes a sputtering gun, a sputter shutter for preventing the metal to be deposited from being spread into the both side thereof during the sputtering process, and a shutter stop for adjusting the aperture of the sputter shutter.

On the other hand, the pumping portion uses a rotary pump and a turbo molecular pump.

The other aspect of the present invention relates to a method for manufacturing a semiconductor device using the apparatus for manufacturing the semiconductor device which comprises the steps of cleaning a substrate on which a semiconductor structure is formed, by using the first chamber; moving the substrate into the second chamber after cleaning the substrate; and depositing a metal film, wherein the steps are performed in batch process, without being exposed to outside air.

The terms “semiconductor structure” means the structure such as an insulator, a semiconductor layer, and a conductor formed by a lithography process and an etching process which is used in the general semiconductor device forming process.

Preferably, the step of heating the substrate after depositing the metal film may be further provided, and the step of growing a sacrificial oxide film in the second chamber before depositing the metal film may be further provided.

The further other aspect of the present invention relates to a method for manufacturing a schottky barrier MOSFET using the apparatus for manufacturing the semiconductor device which comprises the steps of positioning a substrate on which a silicon layer, a gate oxide layer, a gate electrode, a spacer is formed in sequence, in the first chamber; cleaning the substrate by using the first chamber, before depositing a metal film for forming a source/drain electrode; moving the substrate into the second chamber through the connecting portion, after cleaning the substrate; and pulling up the substrate to the upper portion of the second chamber; depositing a metal film by using the metal depositing portion; and pulling down and heating the substrate to form a silicide, after depositing the metal film.

Preferably, the step of growing a sacrificial oxide film in the second chamber before depositing the metal film may be further provided, and the step of cleaning is performed by a vacuum cleaning process or a H₂ baking process, and the sacrificial oxide film before depositing metal is performed in the lower portion of the second chamber.

Preferably, the step of depositing the metal film is performed by using a sputtering method, and the thickness of the deposited metal film is in the range of 50-500 Å, the step of heating the substrate for forming the silicide is performed in the first chamber at the pressure equal to and less than 10⁻⁸ Torr.

### BRIEF DESCRIPTION OF DRAWINGS

FIG. 1 is a diagram showing the cross section of a manufactured schottky barrier MOSFET.

FIG. 2 illustrates an apparatus for manufacturing a SB MOSFET according to an embodiment of the present invention.

FIG. 3 is an enlarged view of a second chamber in the apparatus for manufacturing the SB MOSFET in FIG. 2.

### BEST MODE FOR CARRYING OUT THE INVENTION

Hereinafter, the embodiments of the present invention will be explained with reference to the accompanying drawings. However, these embodiments are provided so that those skilled in the art can understand the present invention and it may be variously changed, and the present invention should not be understood as limited to the specific embodiments thereof.

FIG. 2 illustrates an apparatus for manufacturing the SB MOSFET according to an embodiment of the present invention. The apparatus for manufacturing SB MOSFET comprises a first chamber 100 for performing an in-situ cleaning process, a second chamber 200 for performing a metal depositing process and an in-situ heating process, and a connecting portion including a gate valve 140 and allowing the substrate to be moved between the first chamber 100 and the second chamber 200 without entering outside air thereto.

A quartz panel 108 is provided at the upper portion of the first chamber 100, and a halogen lamp 110 directly irradiates lamp light to the substrate through the quartz panel. The substrate is positioned on a first substrate holder 112 through a substrate door 102. As the halogen lamp 110, the lamp that can perform a rapid thermal processing (RTP) is selected. Also, extra ports (not shown) may be included in the first chamber 100. Extra ports are provided at the both sides of the first chamber 100, and an UV lamp or an electron source is provided thereon, so that the surface reaction of the sample (in relation to the cleaning process) or the heating effect after depositing the metal is increased. In order to generate the electron, a tungsten filament system may be used.

The pressure of the first chamber 100 can be adjusted by a rotary pump 160 and a turbo molecular pump 150. The pressure of the first chamber 100 may be equal to and less than 10⁻⁸ Torr, and a vacuum cleaning process and a vacuum heating process can be performed. At this time, as the heating method, a radial heating process using the above-mentioned halogen lamp 110 can be used. Also, the first chamber 100 is connected with a gas processing portion (not shown) including a separate wiring and a separate valve, thereby a gas such as hydrogen (H₂), nitride (N₂), or Argon (Ar) can be injected.

For example, in case where the pumping speed is increased while injecting the hydrogen gas under the condition that the temperature in the chamber is not less than 750° C. and the pressure is not more than 1 Torr, the cleaning process in the first chamber 100 can remove a natural oxide film on the surface. It is known as a H₂ baking effect, and can prevent the silicon surface from being oxidized again by performing a hydrogen passivation process. Also, the vacuum cleaning process is preformed under the condition that the temperature is in range of 650-750° C. and the pressure is equal to and less than 10⁻⁸ Torr, and the surface oxide film can be removed by the SiO volatile reaction of the oxide film.

The second chamber 200 is connected with the first chamber 100 through the gate valve 140. The gate valve 140 can adjust the pressures of the two chambers, respectively. When the gate valve 140 is opened, the substrate positioned on the first substrate holder 112 is transferred to the second substrate holder 202 positioned in the second chamber by the transporting device 106. Similar to the first chamber 100, the rotary pump 160 and the turbo molecular pump 150 are connected to the second chamber 200, and the pressure of the second chamber 200 can be adjusted by these pumps. In this case, the sample may be moved between the two chambers by a linear motion feedthrough, a movable motor accommodated in the chamber, or a robot arm provided between the chambers. The gate valve 140 is positioned in the center of the tube for connecting the two chambers. The gate valve 140 controls the amount of the gas, adjusts the pressure of the chamber, and it is used as the passage for moving the sample.

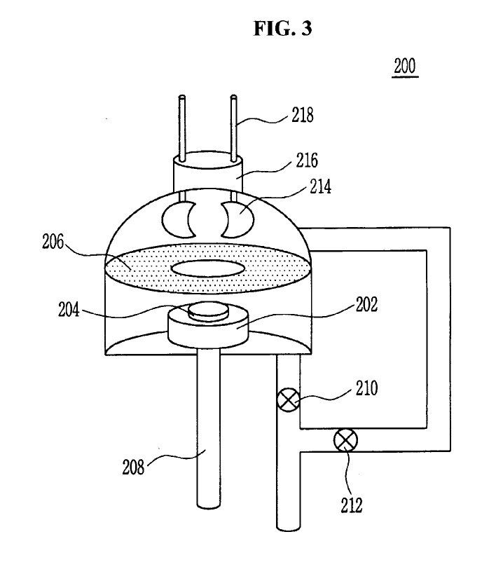

FIG. 3 is an enlarged view of the second chamber 200 in the apparatus for manufacturing the SB MOSFET in FIG. 2. Hereinafter, the second chamber 200 will be explained with reference to FIGS. 2 and 3. The second chamber 200 is used in forming the metal thin film for the SB MOSFET, and the depositing process may be performed by a sputtering method or a vapor depositing method. In the present embodiment, for convenience of the explanation, the sputtering method will be described as an example.

The second chamber 200 comprises the second substrate holder 202. The substrate transferred from the first chamber 100 is positioned on the second substrate holder 202 in FIG. 3. That is, the substrate is mounted on a sample holder 204 and an auto elevating system 208 in order to perform a predetermined process and then is moved toward a middle film 206 in order to perform the sputtering depositing process. The middle film 206 provides the sealed space when the sputtering depositing process is performed. When the sample holder 204 and the second substrate holder 202 on which the substrate is mounted rise up to the middle film, as shown in FIG. 3, the sample holder 204 passes through the hole formed in the center portion of the middle film 206, and the second substrate holder 202 comes into contact with the middle film 206. Therefore, the upper portion and the lower portion of the chamber have different pressures, respectively. For example, for rapidly adjusting the temperature, a separate sample holder 204 is provided on the second substrate holder 202 in the chamber combining a SEG (selective epitaxial growth of silicon) forming apparatus and a sputter for depositing the metal. The substrate holder 202 is located under the sample holder 204, and these holders are provided with a heating element for adjusting the temperature of the sample, respectively. The temperature of the sample (substrate) is adjusted by a ceramic heating element in the second substrate holder 202, and the temperature thereof is adjusted by the a ceramic heating element in the sample holder 204 in case of depositing the metal. In case of the heating element based on a general hot wire, the cooling water is necessary for lowering wall temperature of the chamber. Therefore, in order to lower the temperature rapidly, the sample holder 204 is manufactured as thin as about 1-3 cm. Thermocouples are provided to the sample holder 204 and the second substrate holder 202, and the temperature of the substrate is measured by the thermocouples. On the other hand, it is preferable that the surfaces of the two holders 202 and 204 are not surrounded with a metallic conductor. The TiO₂/Ti of which the surface is oxidized is available for the holder. In the other case, the holder may be coated by a ceramic or may be formed with a film at the circumference thereof.

A sputter gun 216 is provided on the upper portion of the second chamber 200, and a sputter shutter 214 is provided in the front center portion of the second chamber. The sputter shutter 214 prevents the metal deposition from being spread toward the both sides. A shutter stop 218 adjusts the size of the opening of the sputter shutter 214. The sputtering depositing process can be performed at atmosphere of N₂ or Ar, and, in case of the sputtering method, one target is provided in the center of the chamber. However, if necessary, the depositing process can be performed by using three or four targets.

All the cleaning processes are performed in the state that the sputter shutter 214 is closed, and the sample holder 204 is moved to 3-10 cm down the sputter target to be reach to the sputtering depositing location in the meantime. The temperature of the sample holder 204 can be adjusted from an ambient temperature to 500° C. As soon as the sputter shutter is opened, the metal begins to being deposited. The sputter shutter is positioned in the location apart from the sputter target by about 0.5-2 cm in the beginning, but the moment the sputter shutter is opened the sample holders are moved to the both sides thereof Basically, two sputter shutters, each of which has an adjuster, are provided. One sputter gun 216 is basically provided, but, if necessarily, 2-4 sputter guns can be provided, thereby they can be used in the co-deposition or multi-layer thin film deposition.

After the sputtering deposition is finished, the second substrate holder 202 is downwardly moved by the auto elevator. As shown in FIG. 3, on the upper plate of the auto elevator 208, the second substrate holder 202 is provided. The size of sample holder 204 is the smaller than that of the case where the temperature of the substrate is measured by the thermocouple (not shown), the thermocouples are attached to the second substrate holder 202 and the sample holder 204 on the auto elevator 208. The second substrate holder 202 and the sample holder 204 can use a method using a line motion bar or a method using a robot arm. The above-mentioned explanation of the second substrate holder 202 may be adapted to the first substrate holder (112 in FIG. 2).

The carrier gas in the second chamber 200 is independently injected to the upper portion and the lower portion of the middle film 214 by two valves 210 and 212, and the vacuum states of the upper and lower portions can be different from each other. Accordingly, the middle portion of the middle film 214 of the second chamber 200 is perfectly sealed so that ultra high vacuum and cleanliness can be maintained.

Hereinafter, the example of the process for manufacturing the SB MOSFET by the second chamber 200 will be described. In order to relax the crystal interface and form a sacrificial layer before depositing the metal by using the second chamber 200, the SEG can be deposited based on the ultra high vacuum CVD method (UHVCVD). When Si₂H₆ gas which is the silicon source flows at a certain amount under the condition that the temperature of the substrate is maintained at 550-700° C. and the basic pressure is equal to and less than 10⁻⁸ Torr, a single crystal silicon film having thickness of 200-500 Å can be selectively grown on only an active portion. In order to implement the SEG using the UHVCVD, GeH₄ gas as well as the silicon are injected such that the SiGe SEG is implemented. In other words, the sample (or the substrate) moved from the first chamber 100 is positioned on the second substrate holder 202 of the second chamber 200, and the SEG process can be progressed when the temperature is reached to a certain value. After the SEG process is finished, the sample holder 202 is upwardly moved by the 5-20 cm by means of the auto elevator 208, and then the metal film is deposited by using the sputtering method. The auto elevator 208 may have a self-rotation function.

The sacrificial silicon growth and the metal film deposition may be progressed in separate chambers, respectively. In case where the metal film deposition process and the SEG process can not coexist, they are divided to form clusters. The in-situ process may be performed and the sample may be moved by the robot arm.

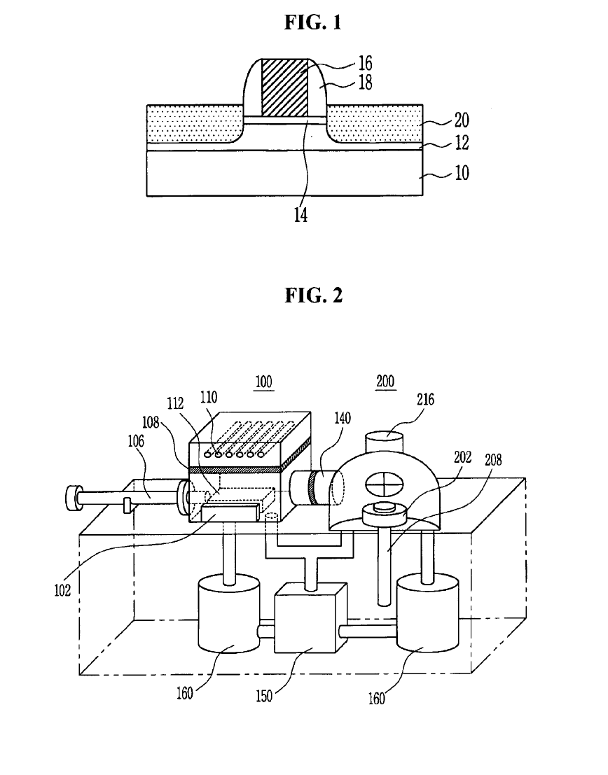

Hereinafter, the process for manufacturing the schottky barrier MOSFET with reference to FIG. 1.

A silicon layer 12 is formed on an insulating film 10 of a SOI (Silicon On Insulator) substrate. A gate oxide film 14 is formed on the silicon layer 12, and a gate electrode 16 is formed on the gate oxide film 14, and then a spacer 18 is formed and is etched.

Next, a series of the processes such as the cleaning process before the metal deposition process, the sacrificial oxide film growth process before the metal deposition process, the metal deposition process, and the heating process for silicide-reaction after the metal deposition process are performed by using the apparatus for manufacturing the SB MOSFET. In this case, it is preferable that the cleaning process before the metal deposition process and the heating process for silicide-reaction after the metal deposition process are performed in the first chamber and the sacrificial oxide film growth process before the metal deposition process and the metal deposition process are preformed in the second chamber. By such method, the batch process can be preformed, without exposing the substrate to the outside air, during the above-mentioned process.

First, the cleaning process before the metal deposition process can have the ex-situ cleaning process and the in-situ cleaning process, wherein the ex-situ cleaning process performs the post-etching treatment based on a low power plasma and the cleaning process based on the wet etching bath after the pattern is etched.

The low power plasma treatment in the ex-situ cleaning process is to efficiently remove the damage layer formed after the gate electrode is formed. For example, the low power plasma treatment can be performed under the condition that NF₃ gas of 10-50 sccm, O₂ gas of 20-100 sccm, and He or Ar gas of 50-2000 sccm are injected, the power is 5-50 W and the pressure is 0.1-5 mTorr. The removal of the oxide film according to the wet etching bath is preformed by using a diluted HF solution. The HF solution is diluted to 50-500:1 with DI (Deionized) water. Before the HF solution treatment, organic materials are removed by a diluted sulfuric acid (H₂SO₄: H₂O₂=1:1), during 60-600 seconds. The sample treated by the HF solution passivates the surface thereof with the hydrogen by at least 90%.

Next, when the sample is positioned in the first chamber (100 in FIG. 2) in order to perform the in-situ cleaning process, a vacuum cleaning process or a H₂ baking process are performed. The vacuum cleaning process is performed at the temperature of 650-750° C. and the ultra vacuum state which the pressure is equal to and less than 10⁻⁸ Torr, during 60-300 seconds. The H₂ baking process is performed during 60-300 seconds, under the condition that the H₂ gas flows in the extent of 0.5-50 slm, the pressure is as low as 0.1-10 Torr and the temperature is in 700-900° C.

The sacrificial oxide film forming process before the metal deposition process is performed by a UHVCVD method after the in-situ cleaning process. That is, the substrate is maintained at the pressure equal to and less than 10⁻⁸ Torr and the temperature of 550-750° C. during 100-500 seconds and Si₂H₆ or SiH₄ gas of 1-50 sccm is injected into the chamber, thereby a selective epitaxial silicon layer having the thickness of 100-500 Å is grown. On the other hand, SiGe SEG can be adapted as the sacrificial oxide film. The SiGe SEG is deposited by the UHVCVD method. That is, the substrate is maintained at the pressure equal to and less than 10⁻⁸ Torr and the temperature of 550-750° C. during 100-500 seconds and Si₂H₆ or GeH₄ gas of 1-50 sccm is injected into the chamber, thereby the SiGe SEG having the thickness of 100-500 Å is grown. On the other hand, the sacrificial oxide forming process before the metal deposition process can be omitted. After the deposition of the SEG is completed, the sample holder is upwardly moved by about 5-20 cm by using the auto elevator and then the metal deposition process is performed.

The metal deposition process is performed at the pressure of 0.005-50 Torr and the Ar or N₂ atmosphere. All the cleaning process is performed in the state that the sputter shutter is closed, and metal deposition process begins as soon as the sample holder is moved under the sputter target to be reached to the sputtering deposition location and sputter shutter is opened. The thickness of the deposited metal film is, for example, 50-500 Å. After the metal film is deposited, the sample holder is returned to the original location (over the substrate holder) again.

Next, the heating process for forming the silicide after the metal deposition process can be performed in a separate chamber, and the in-situ cleaning process can be performed by using the first chamber. The cleaning process before the metal deposition process and the heating process for forming silicide are simultaneously performed. A quartz panel is provided under the halogen lamp, and the heating speed can be, for example, 10-100° C./sec. The pressure can be equal to and less than 10⁻⁸ Torr and the heating process for the silicide reaction can use a rapid thermal process and isothermal process. The formation of silicide by the rapid thermal process is generally termed as a primary thermal process and the rapid thermal process of 500-1200° C. (0-60 sec) is adapted according to the kind of the metal. On the other hand, the isothermal process that is a secondary thermal process is performed at the low temperature of 200-800° C. during 30-300 minutes. According to the kind of the metal, only the primary thermal process is performed, or both the primary and secondary thermal process are performed. That is, the thermal process can be determined by the metal.

### INDUSTRIAL APPLICABILITY

In the method of manufacturing the hyperfine SB MOSFET, the optimization of the process can be accomplished. Since the cleaning process can be performed in situ during the metal deposition process and the silicide thermal process can be performed in situ after the metal deposition, the attachment of unnecessary impurities and the unnecessary oxidation can be prevented. Also, since the cleaning process before the metal deposition process and the thermal process after the metal deposition process can be performed in one chamber, the cost of the equipment can be reduced and the necessary space can be removed. Because the UHVCVD SEG process and the metal deposition process can be performed the same chamber, the optimization of the process can be accomplished and the economical gain can be obtained.

Although the present invention has been illustrated and described with respect to exemplary embodiments thereof, the present invention should not be understood as limited to the specific embodiment, and it should be understood by those skilled in the art that the foregoing and various other changes, omission and additions may be made therein and thereto, with departing from the spirit and scope of the present invention.

1. An apparatus for manufacturing a semiconductor device, comprising:
a first chamber having a first substrate holder provided in the lower portion of the first chamber for mounting a sample thereon, a halogen lamp provided in the upper portion of the first chamber for irradiating lamp light to the sample, and a substrate door through which the sample passes;
a second chamber having a temperature-adjustable second substrate holder provided in the lower portion of the second chamber for mounting the sample thereon, a middle film provided in the middle portion of the second chamber for dividing the chamber into an upper portion and a lower portion, an elevating portion attached to said second substrate holder for moving said second substrate holder into the upper portion or the lower portion on the basis of the middle film, and a metal depositing portion provided in the upper portion of the second chamber;
pumping portions connected to said first chamber and said second chamber, for adjusting the pressures thereof, respectively;
gas injecting portions connected to said first chamber and said second chamber, for injecting a gas by a certain amount, respectively; and
a connecting portion for allowing the sample to reciprocally moving between said first chamber and said second chamber without injecting outside air, and
the connecting portion including a gate valve.

2. The apparatus for manufacturing the semiconductor device according to claim 1, wherein said metal depositing portion includes a sputtering gun, a sputter shutter for preventing the metal to be deposited from being spread into the both side thereof during the sputtering process, and a shutter stop for adjusting the aperture of the sputter shutter.

3. The apparatus for manufacturing the semiconductor device according to claim 1, wherein said pumping portion uses a rotary pump and a turbo molecular pump.

4. The apparatus for manufacturing the semiconductor device according to claim 1, further comprising thermocouples attached to said first substrate holder and said second substrate holder for measuring the temperatures of said first chamber and said second chamber, respectively.

5. The apparatus for manufacturing the semiconductor device according to claim 1, further comprising a port provided on the side surface of said first chamber for providing an UV lamp or an electronic source.

6-14. (canceled)
